(19) United States
(12) Patent Application Publication
(10) Pub. No.: US 2012/0318319 A1
(43) Pub. Date: Dec. 20, 2012

(54) METHODS OF INTERCONNECTING THIN FILM SOLAR CELLS

(75) Inventors: Mustafa Pinarbasi, Morgan Hill, CA (US); Burak Metin, San Jose, CA (US)

(73) Assignee: SoloPower, Inc., San Jose, CA (US)

(21) Appl. No.: 13/253,921

(22) Filed: Oct. 5, 2011

Related U.S. Application Data
(63) Continuation-in-part of application No. 13/163,485, filed on Jun. 17, 2011.

(51) Int. Cl. H01L 31/05; H01L 31/18

(52) U.S. Cl. 136/244; 438/80; 257/E33.001

(57) ABSTRACT

A photovoltaic module comprises a first group of solar cells; a second group of solar cells; a first interconnection member extending across a first surface of the first group of solar cells and across a first surface of the second group of solar cells to connect the first and second groups of solar cells in parallel; and a second interconnection member extending across a second surface of the first group of solar cells and across a second surface of the second group of solar cells.

### RELATED APPLICATIONS

This application is a continuation-in-part of U.S. patent application Ser. No. 13/163,485, filed on Jun. 17, 2011, entitled “CIGS BASED THIN FILM SOLAR CELLS HAVING SHARED BYPASS DIODES” which is hereby incorporated by reference in its entirety.

### BACKGROUND

1. Field of the Inventions

Embodiments of the present invention generally relate to photovoltaic or solar module design and fabrication and, more particularly, to modules utilizing thin film solar cells.

2. Description of the Related Art

Solar cells are photovoltaic (PV) devices that convert sunlight directly into electrical energy. Solar cells can be based on crystalline silicon or thin films of various semiconductor materials, that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells including copper indium gallium diselenide (CIGS) based solar cells have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂, is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or the contact layer formed on the substrate as an absorber precursor, and are then reacted with S and/or Se in a high temperature annealing process.

After the absorber film 14 is formed, a transparent layer 15, for example, a CdS film, a ZnO film or a CdS/ZnO film-stack, is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

There are two different approaches for manufacturing PV modules. In one approach that is applicable to thin film CdTe, amorphous Si and CIGS technologies, the solar cells are deposited or formed on an insulating substrate such as glass that also serves as a back protective sheet or a front protective sheet, depending upon whether the device is “substrate-type” or “superstrate-type”, respectively. In this case the solar cells are electrically interconnected as they are deposited on the substrate. In other words, the solar cells are monolithically integrated on the single-piece substrate as they are formed. These modules are monolithically integrated structures. For CdTe thin film technology, the superstrate is glass which also is the front protective sheet for the monolithically integrated module. In CIGS technology, the substrate is glass or polyimide and serves as the back protective sheet for the monolithically integrated module. In monolithically integrated module structures, after the formation of solar cells which are already integrated and electrically interconnected in series on the substrate or superstrate, an encapsulant is placed over the integrated module structure and a protective sheet is attached to the encapsulant. An edge seal may also be formed along the edge of the module to prevent water vapor or liquid transmission through the edge into the monolithically integrated module structure.

In standard CIGS as well as Si and amorphous Si module technologies, the solar cells can be manufactured on flexible conductive substrates such as aluminum or stainless steel foils. Due to its flexibility, a stainless steel substrate allows low cost roll-to-roll solar cell manufacturing techniques. For such cells that are fabricated on conductive substrates, the solar cells are not formed on the protective sheet, and the transparent layer and the conductive substrate form the opposite poles of the solar cells. Multiple solar cells can be electrically interconnected by stringing or shingling methods that establish electrical connection between the opposite poles of the solar cells. Such interconnected solar cells are then packaged in protective packages to form solar modules or panels. Many modules can also be combined to form large solar panels. The solar modules are constructed using various packaging materials to mechanically support and protect the solar cells contained in the packaging against mechanical damage. Each module typically includes multiple solar cells which are electrically connected to one another using the above mentioned stringing or shingling interconnection methods.

In the stringing or shingling process, the (+) terminal of one cell is typically electrically connected to the (−) terminal of the adjacent solar cell. For the Group IBIIIAVIA compound solar cell shown in FIG. 1, if the substrate 11 is a conductive material such as a metallic foil, the substrate, which forms the bottom contact of the cell, becomes the (+) terminal of the solar cell. The metallic grid (not shown) deposited on the transparent layer 15 is the top contact of the device and becomes the (−) terminal of the cell. When interconnected by a shingling process, individual solar cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. Stringing is typically done by placing the cells side by side with a small gap between them and using conductive wires or ribbons that connect the (+) terminal of one cell to the (−) terminal of an adjacent cell. Solar cell strings obtained by stringing or shingling individual solar cells are interconnected to form circuits. Circuits may then be packaged in protective packages to form modules. Each module typically includes a plurality of strings of solar cells which are electrically connected to one another.

As shown in FIG. 2B in a cross-sectional view, the PV module 50 such as shown in FIG. 2A is constructed using various packaging materials to mechanically support and protect the solar cells in it against mechanical and moisture damage. The most common packaging technology involves lamination of circuits in transparent encapsulants. In a lamination process, in general, the electrically interconnected solar cells 52 are covered with a transparent and flexible encapsulant layer 58 which fills any hollow space among the cells and tightly seals them into a module structure, preferably covering both of their surfaces. A variety of materials are used as encapsulants, for packaging solar cell modules, such as ethylene vinyl acetate copolymer (EVA), thermoplastic polyurethanes (TPU), and silicones. However, in general, such encapsulant materials are moisture permeable; therefore, they must be further sealed from the environment by a protective shell, which forms resistance to moisture transmission into the module package. The nature of the protective shell 56 determines the amount of water vapor that can enter the module 50. The protective shell 56 typically includes a front protective sheet 60A and a back protective sheet 60B and optionally an edge sealant 60C that is at the periphery of the module structure. The top protective sheet 60A is typically glass which is water impermeable. The back protective sheet 60B may be a sheet of glass or a polymeric sheet. The back protective sheet 60B may not have a moisture barrier layer in its structure such as a metallic film like an aluminum film. Light enters the module through the front protective sheet 60A. The edge sealant 60C is a moisture barrier material that may be in the form of a viscous fluid which may be dispensed from a nozzle to the peripheral edge of the module structure or it may be in the form of a tape which may be applied to the peripheral edge of the module structure. The edge sealant in Si-based modules is not between the top and bottom protective sheets but rather in a frame 65 which is attached to the edge of the module.

Flexible module structures may be constructed using flexible CIGS or amorphous Si solar cells. Flexible modules are light weight, and unlike the standard glass based Si solar modules, are unbreakable. Therefore, packaging and transportation costs for the manufactured flexible modules are much lower than for solar cell or module structures formed on glass that are not flexible and are easily damaged by mishandling. However, manufacture of flexible module structures is challenging in respects that are different from solar cell and module structures formed on glass that are not flexible. Further, while glass handling equipment used in glass based PV module manufacturing is fully developed by many equipment suppliers, handling of flexible sheets cannot be carried out using such standard equipment, and different equipment is required. Further, requirements are different for the flexible sheets that constitute the various layers in the flexible module structure. Various layers in flexible module structures may be cut into sizes that are close to the desired area of the module and encapsulation procedures may be carried out by handling and moving these pieces around.

As shown in FIGS. 2A-2B, solar cells 52 are typically interconnected in series to form circuits, which are then encapsulated to form the PV module 50. One important point relating to series connection of solar cells relates to shading of individual cells. If any one of the cells 52 in a cell string within a module is shadowed for a period, the shadowed cell may become reverse-biased due to the shadowing, in contrast to the other cells that receive light and are operational. Such reverse biasing of individual cells may cause breakdown of that cell and its overheating, and degradation of the overall module output. To avoid such problems it is customary to use bypass diodes which are placed into a junction box 62 attached to the back protective sheet 60B of the PV module 50.

FIG. 3 illustrates a common electrical interconnection configuration for groups of solar cells 52 connected to bypass diodes. Although FIG. 3 represents a shingled configuration, such that a substrate portion of the second solar cell overlaps with a surface portion of the first solar cell, the same interconnections shown can be made for a stringing configuration. As shown, a bypass diode 72 is used for every group of 3 solar cells 52. For standard Si technology, the reverse breakdown voltage of the Si solar cells is large enough that a bypass diode may be used for every string containing 18-24 solar cells. Therefore, in Si solar modules 1, 2 or 3 bypass diodes are typically placed into junction boxes, which are attached onto the back surface of the modules, and these diodes are connected to the appropriate points on the cell strings within the module package. The reverse breakdown voltages of thin film solar cells such as amorphous Si or CIGS devices fabricated on flexible metallic substrates are much lower than those of Si solar cells. CIGS devices, for example, may display a reverse breakdown voltage in the range of 1-6V, compared to Si solar cells which typically have breakdown voltages more than 10V. This means that, high power thin film solar modules such as over 100W CIGS modules may need more than 10 bypass diodes to properly protect the cells and assure that modules perform safely without hot spots. However, bypass diodes are expensive, and it is not practical to place so many bypass diodes in a junction box outside the module package. Therefore, there is a need for a way to make solar cells with bypass diode protection in a less expensive manner.

### SUMMARY

The aforementioned needs are satisfied by embodiments of the present invention which, in a photovoltaic module comprises: a first group of solar cells; a second group of solar cells; a first interconnection member extending across a first surface of the first group of solar cells and across a first surface of the second group of solar cells to connect the first and second groups of solar cells in parallel; and a second interconnection member extending across a second surface of the first group of solar cells and across a second surface of the second group of solar cells. The second group of solar cells may be connected to a first bypass diode, and the second interconnection member may connect the first group of solar cells to the first bypass diode.

In one implementation, the first group of solar cells in the photovoltaic module comprises a first solar cell connected in series to a second solar cell, and the second group of solar cells in the photovoltaic module comprises a first solar cell connected in series to a second solar cell. The bypass diode may be disposed over the second surface of the second group of solar cells. The bypass diode may be connected to the first and second groups of solar cells such that the bypass diode inhibits reverse bias of the first or second group of solar cells when one or more cells of the first or second groups of solar cells are reverse biased. The second interconnection member may be configured to direct current through the first or second group of solar cells.

In one implementation, the first group of solar cells is arranged in a shingled relationship such that a surface of the second solar cell comprising a terminal of a first polarity contacts a surface of the first solar cell comprising a terminal of a second polarity opposite the first polarity, and the second group of solar cells is arranged in such a shingled relationship.

In another implementation, the first group of solar cells comprises a third solar cell connected in series to the second solar cell, wherein the second group of solar cells comprises a third solar cell connected in series to the second solar cell.

In another implementation, the photovoltaic module may comprise a third group of solar cells; a fourth group of solar cells connected to a second bypass diode; and a third interconnection member extending across a first surface of the third group of solar cells and across a first surface of the fourth group of solar cells to connect the third group of solar cells to the bypass diode, wherein the third group of solar cells is connected in series to the first group of solar cells, and wherein the fourth group of solar cells is connected in series to the second group of solar cells.

In another implementation, a method of interconnecting a PV module, comprises: connecting a plurality of solar cells in a first group of solar cells; connecting a plurality of solar cells in a second group of solar cells; connecting the first group of solar cells and the second group of solar cells in parallel by a first interconnection member extending across a first surface of the first group of solar cells and across a first surface of the second group of solar cells; and connecting the first group of solar cells and the second group of solar cells by a second interconnection member extending across a second surface of the first group of solar cells and across a second surface of the second group of solar cells.

### BRIEF DESCRIPTION OF THE DRAWINGS

FIG. 1 is a schematic view of a thin film solar cell;

FIG. 2A is a schematic top view of a prior art photovoltaic module;

FIG. 2B is a schematic cross sectional view of the module of FIG. 2A;

FIG. 3 is a schematic view of a prior art photovoltaic module including bypass diodes;

FIG. 4 is a schematic view of a photovoltaic module according to an embodiment of the invention including bypass diodes;

FIG. 5 is a schematic view of a photovoltaic module according to another embodiment of the invention including bypass diodes;

FIG. 6 is a schematic top view of a strings of interconnected photovoltaic cells;

FIG. 7 is a schematic top view of a photovoltaic module including an interconnection member;

FIG. 8 is a schematic top view of a photovoltaic module including an interconnection member;

FIG. 9a is a schematic view of a photovoltaic module including an interconnection member and a bypass diode assembly;

FIG. 9b is a schematic cross sectional view of a photovoltaic module including an interconnection member and a bypass diode assembly;

FIG. 10 is a schematic cross sectional view of a photovoltaic module including an interconnection member;

FIG. 11 is a schematic top view of a photovoltaic module including an interconnection member and lead extensions;

FIG. 12a is a schematic cross sectional view of a photovoltaic module including an interconnection member and lead extensions;

FIG. 12b is a schematic cross sectional view of a photovoltaic module including an interconnection member and lead extensions;

FIG. 13 is a schematic cross sectional view of a photovoltaic module including an interconnection member and lead extensions; and

FIG. 14 is a schematic top view of a photovoltaic module including an interconnection member and lead extensions.

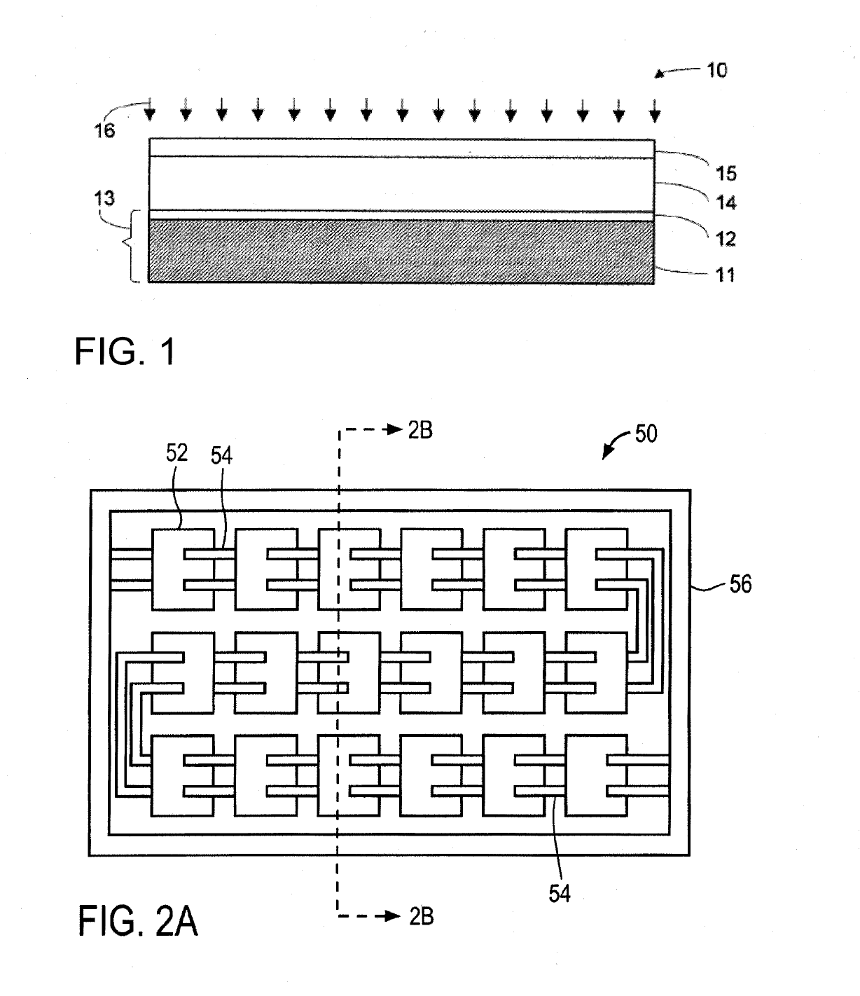

### DETAILED DESCRIPTION OF THE PREFERRED EMBODIMENTS

The embodiments described herein provide methods of interconnecting solar cells or photovoltaic (PV) cells. Embodiments will be described with reference to specific interconnected solar cell configurations or arrays. However, it will be appreciated that embodiments of the present invention may be practiced with other configurations without departing from the scope of the present invention.

Embodiments described herein provide module structures and methods of manufacturing rigid or flexible PV modules employing thin film solar cells fabricated on flexible substrates, preferably on flexible metallic foil substrates. The solar cells may be Group IBIIIAVIA compound solar cells fabricated on thin stainless steel or aluminum alloy foils. The modules may each include a moisture resistant protective shell within which the interconnected solar cells or cell strings are packaged and protected. The protective shell may comprise a moisture barrier top protective sheet through which the light may enter the module, a moisture barrier bottom protective sheet, a support material or encapsulant covering at least one of a front side and a back side of each cell or cell string. The support material may be used to fully encapsulate each solar cell and each string, top and bottom. The protective shell may additionally comprise a moisture sealant that is placed between the top protective sheet and the bottom protective sheet along the circumference of the module and forms a barrier to moisture passage from outside into the protective shell from the edge area along the circumference of the module. At least one of the top protective sheet and the bottom protective sheet of the present module may be glass for rigid structures. For flexible modules, the top and bottom protective sheets may be flexible materials that have a moisture transmission rate of less than 10⁻³ gm/m²/day, preferably less than 5×10⁻⁴ gm/m²/day.

In one embodiment, a solar cell string including two or more solar cells is formed by interconnecting the solar cells. At least one bypass diode may be connected in parallel but with opposite polarity to the solar cells, as further described below. The bypass diodes may be placed into a junction box that is attached to the exposed back protective sheet of the PV module, right below the interconnected solar cells, using moisture barrier adhesives. Terminals of the interconnected solar cells may be connected to the junction box through holes formed in the back protective sheet. In this way, the size of the module may be maintained as the frame holding the cells can be positioned very close to the solar cells. The holes in the back protective sheet must be very carefully sealed against moisture leakages using, for example, potting materials such as silicone, epoxy, butyl, and urethane containing materials. If the seal in the holes fails, such holes allow moisture to enter the module and can cause device failures. Alternatively, the bypass diode may be electrically connected to the conductive back surfaces of at least two solar cells, each solar cell having a back conductive surface and a front light receiving surface. The bypass diode and the solar cells may be further encapsulated with support material such that the bypass diode is placed between at least one solar cell and the bottom protective sheet.

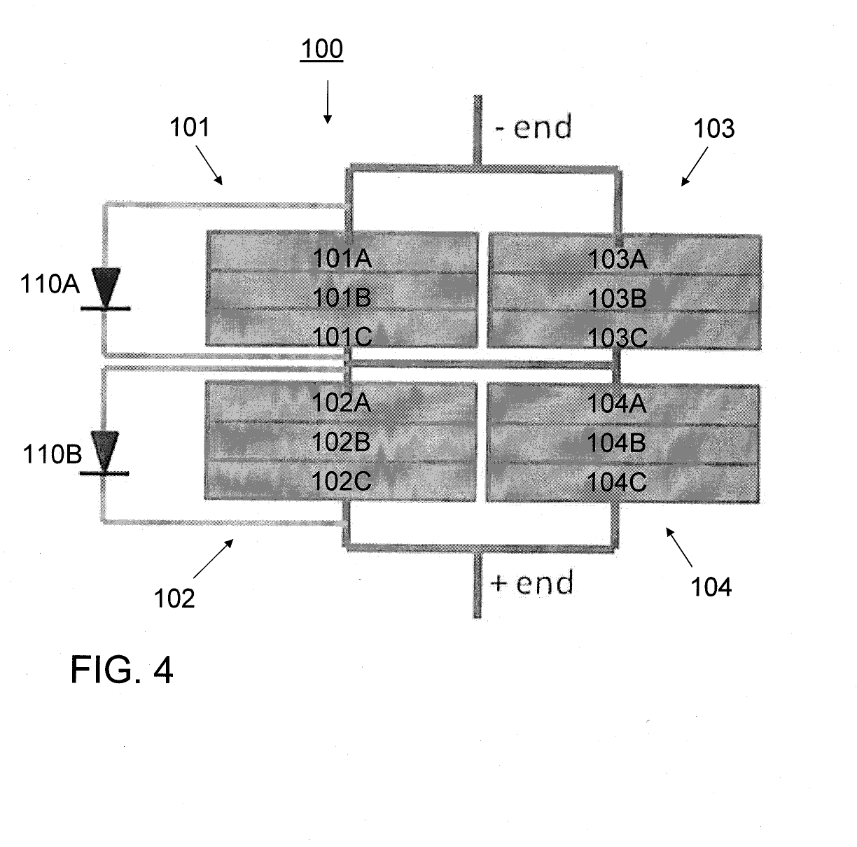

FIG. 4 shows a schematic view of a PV module 100, which includes cell group 101, including solar cells 101A, 101B and 101C, cell group 102, including solar cells 102A, 102B and 102C, cell group 103, including solar cells 103A, 103B and 103C, and cell group 104, including solar cells 104A, 104B and 104C. Although FIG. 4 represents a shingled solar cell configuration, such that a substrate portion of the second solar cell overlaps with a surface portion of the first solar cell, the same interconnections shown can be made for a stringing solar cell configuration.

Specifically, in cell group 101, the top surface of solar cell 101A is a (−) terminal, and the bottom surface of solar cell 101A is a (+) terminal, which connects in series to the top surface of solar cell 101B, which is a (−) terminal. The bottom surface of solar cell 101B is a (+) terminal, which connects in series to the top surface of solar cell 101C, which is a (−) terminal. The bottom surface of solar cell 101C is a (+) terminal, and connects to cell group 102, by connecting in series to the top surface of solar cell 102A, which is a (−) terminal.

Likewise, in cell group 103, the top surface of solar cell 103A is a (−) terminal, and the bottom surface of solar cell 103A is a (+) terminal, which connects in series to the top surface of solar cell 103B, which is a (−) terminal. The bottom surface of solar cell 103B is a (+) terminal, which connects in series to the top surface of solar cell 103C, which is a (−) terminal. The bottom surface of solar cell 103C is a (+) terminal, and connects to cell group 104, by connecting in series to the top surface of solar cell 104A, which is a (−) terminal.

In the illustrated embodiment, a bypass diode 110A is connected to the pair of cell groups 101/103, and a bypass diode 110B is connected to the pair cell groups 102/104. In contrast to the interconnection configuration in FIG. 3, in which each solar cell group is interconnected to adjacent solar cells in series, in the illustrated embodiment, the cell groups 101 and 103 are connected to each other in parallel, while cell groups 102 and 104 are also connected to each other in parallel. Moreover, in FIG. 3, a bypass diode is used for every 3 solar cells in each cell group. In contrast, in the embodiment of FIG. 4, a pair of parallel-connected cell groups 101/103 is connected in series to a pair of parallel-connected cell groups 102/104, and therefore one bypass diode is used for each pair of cell groups. Thus, the number of bypass diodes in the illustrated embodiment is reduced in half compared to the number of bypass diodes in the example of FIG. 3, for the same number of cells arranged on the same surface area of a PV module. Accordingly, embodiments of the invention can significantly reduce material costs, by at least a half compared to conventional devices, due to the reduced total number of bypass diodes used.

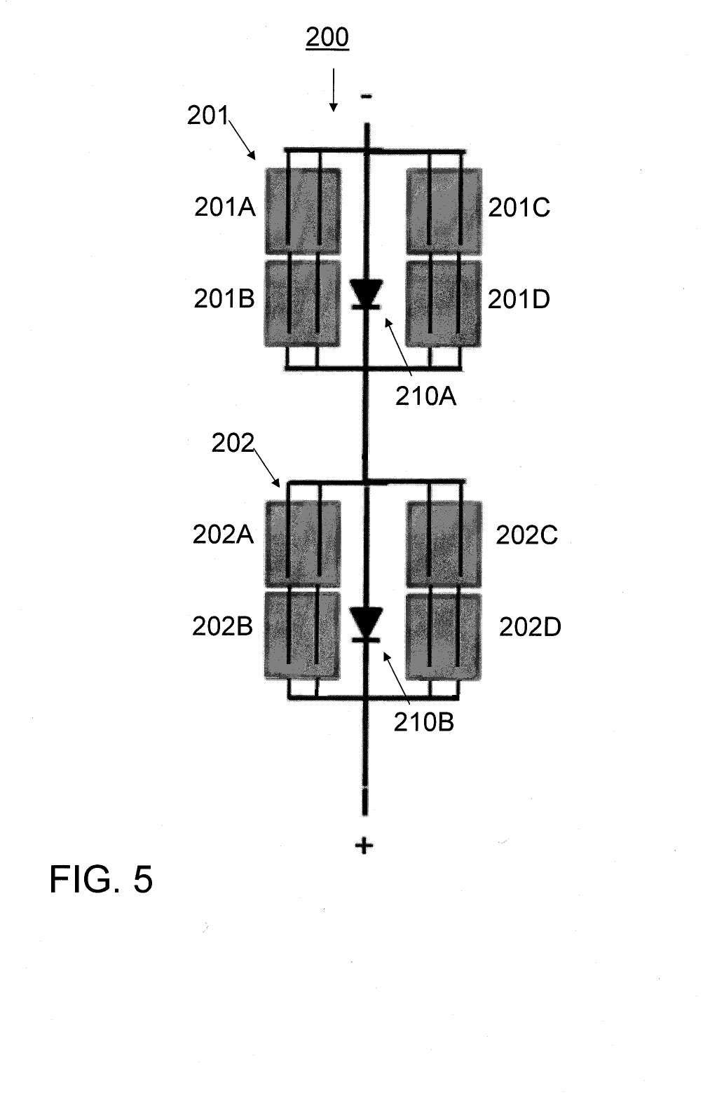

FIG. 5 shows a schematic view of a PV module 200, which includes cell group 201, including solar cells 201A, 201B, 201C and 201D, and cell group 202, including solar cells 202A, 202B, 202C and 202D. Specifically, for the cell group 201, the top surface of solar cell 201A is a (−) terminal, and the bottom surface of solar cell 201A is a (+) terminal, which connects in series to the top surface of solar cell 201B, which is a (−) terminal. Likewise, the top surface of solar cell 201C is a (−) terminal, and the bottom surface of solar cell 201C is a (+) terminal, which connects in series to the top surface of solar cell 201D, which is a (−) terminal. The pair of serial-connected solar cells 201A/201B is connected to the pair of serial-connected solar cells 201C/201D in parallel. A bypass diode 210A is connected to the cell group 201, including solar cells 201A, 201B, 201C and 201D.

Similarly, for the cell group 202, the top surface of solar cell 202A is a (−) terminal, and the bottom surface of solar cell 202A is a (+) terminal, which connects in series to the top surface of solar cell 202B, which is a (−) terminal. Likewise, the top surface of solar cell 202C is a (−) terminal, and the bottom surface of solar cell 202C is a (+) terminal, which connects in series to the top surface of solar cell 202D, which is a (−) terminal. The pair of serial-connected solar cells 202A/202B is connected to the pair of serial-connected solar cells 202C/202D in parallel. A bypass diode 210B is connected to the cell group 202, including solar cells 202A, 202B, 202C and 202D. The cell group 201 is thus connected to the cell group 202 in series, with a single bypass diode for each group of 4 interconnected solar cells.

Although FIG. 5 represents a stringing configuration, the same interconnections shown can be made for a shingled configuration. Moreover, the cells in each cell group that are connected in series, for example, solar cells 201A and 201B, or solar cells 201C and 201D, may also be in a shingled relationship such that one surface of a solar cell directly contacts and overlaps with another surface of an adjacent solar cell.

Thus, embodiments of the invention further reduce overall mismatch power losses by connecting groups of cells in parallel to each other. For example, for a solar cell configuration with an all-series interconnection scheme, current mismatches may affect the overall output of the module as the cell with the lowest current will control the overall module output. However, for interconnection schemes according to the embodiments shown for example in FIG. 4 and FIG. 5, the mismatches in both voltage and current may be accommodated because there is always a secondary path within the parallel paired cells 101/103 and 102/104 as shown in FIGS. 4, and 201A-B/201C-D and 202A-B/202C-D as shown in FIG. 5. Thus, embodiments of the invention can reduce problems of power losses due to current and voltage mismatches.

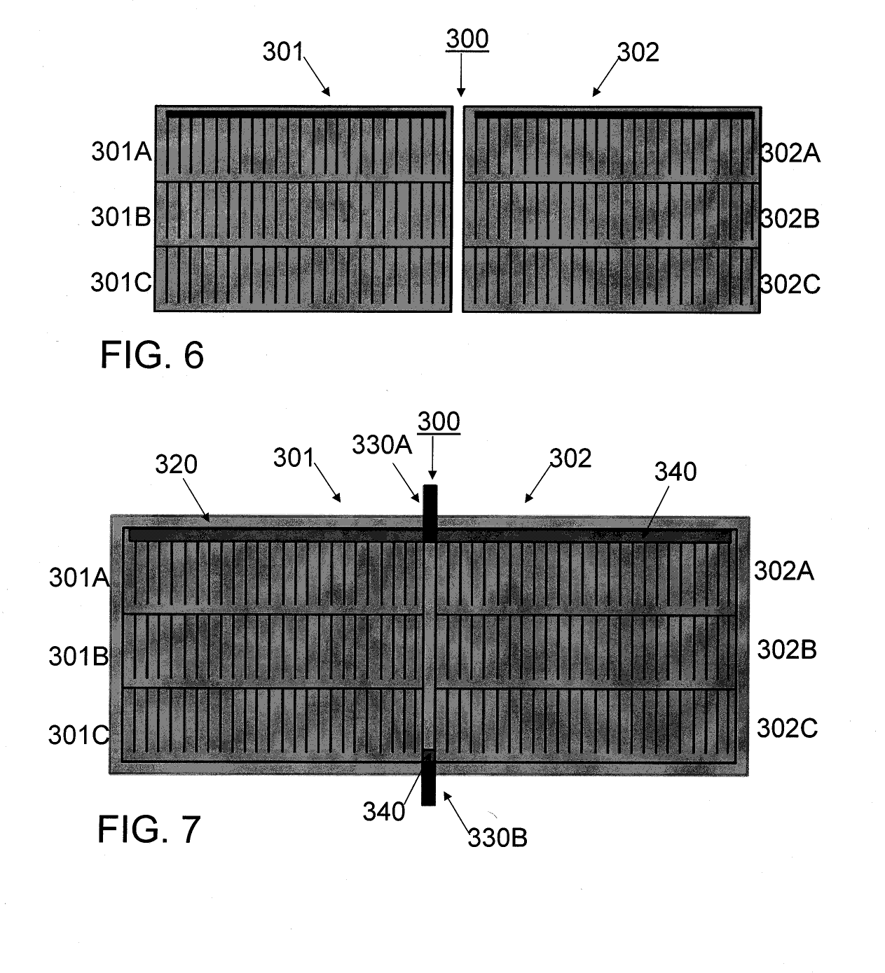

FIG. 6 shows a schematic view of strings of interconnected PV cells 300, which includes cell group 301, including solar cells 301A, 301B and 301C, and cell group 302, which includes solar cells 302A, 302B and 302C. Although there are three cells in each cell group in the illustrated embodiment, the number of cells for each cell group can be different in other embodiments, for example, from 2-20 solar cells per cell group. In the illustrated embodiment, the cells in each cell group, 301 and 302, are shingled such that a substrate portion of solar cell 301A overlaps with a surface portion of solar cell 301B, and a substrate portion of solar cell 301B overlaps with a surface portion of solar cell 301C. The cells may be coupled to each other by an adhesive or a solder material at the interface between two adjacent cells.

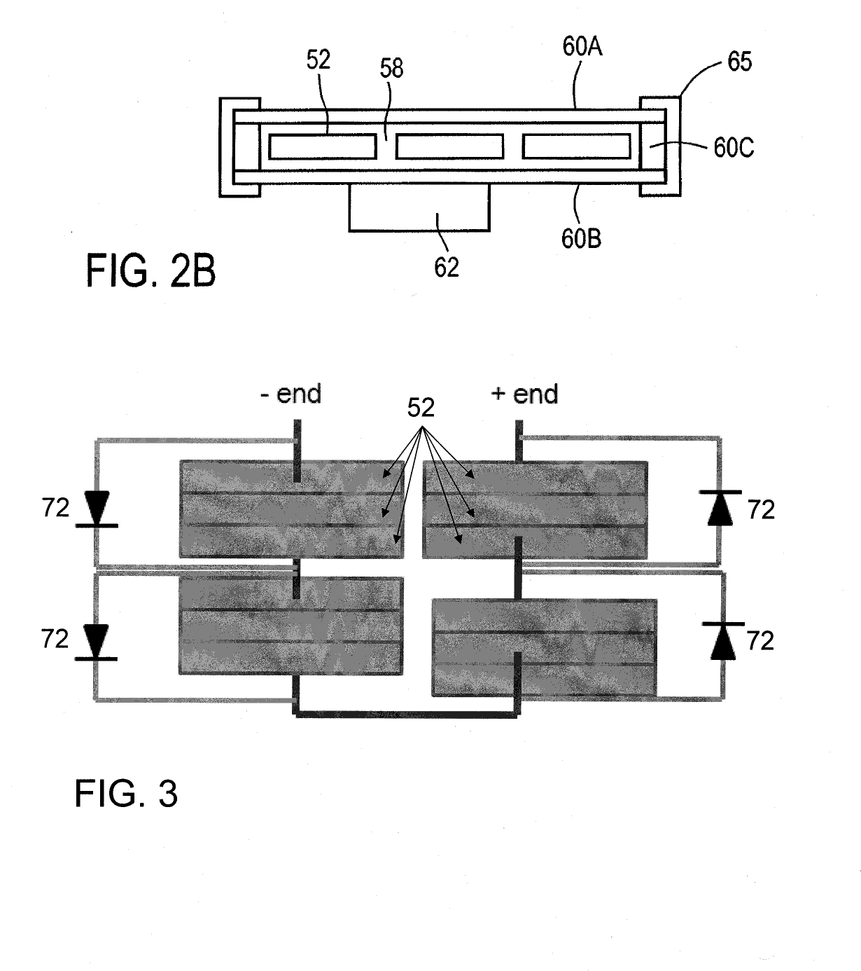

FIG. 7 shows a schematic view of interconnected strings 300, shown positioned in a solar panel 320 according to a preferred embodiment of the present invention. The cells in the panel are arranged such that the side of each solar cell with the smaller width is aligned to the side of the panel with the smaller width, and the side of each solar cell with the larger length is aligned to the side of the panel with the larger length. As noted above, the cells in each cell group are shingled. By aligning the longer side of the cells in a shingled arrangement with the longer side of the panel, the space on the panel 320 can be efficiently utilized compared to conventional PV modules, for example, shown in FIG. 2A.

The cell groups 301 and 302 may be connected to each other in parallel with an interconnecting member 340, as shown in FIG. 7. The interconnecting member 340 may be a bus ribbon, and may be formed of various conductive materials. The bus ribbon may be formed of a conductive material. In the illustrated embodiment, the interconnecting member 340 is a bus ribbon formed of a copper base film plated or coated with a Sn (tin) and Ag(silver) alloy. In other embodiments, the interconnecting member may be formed of other metallic materials, such as tin, nickel, bismuth, or the like. The negative end of the interconnected strings will lead to junction box or the next set of strings via 330A, and the positive lead via 330B.

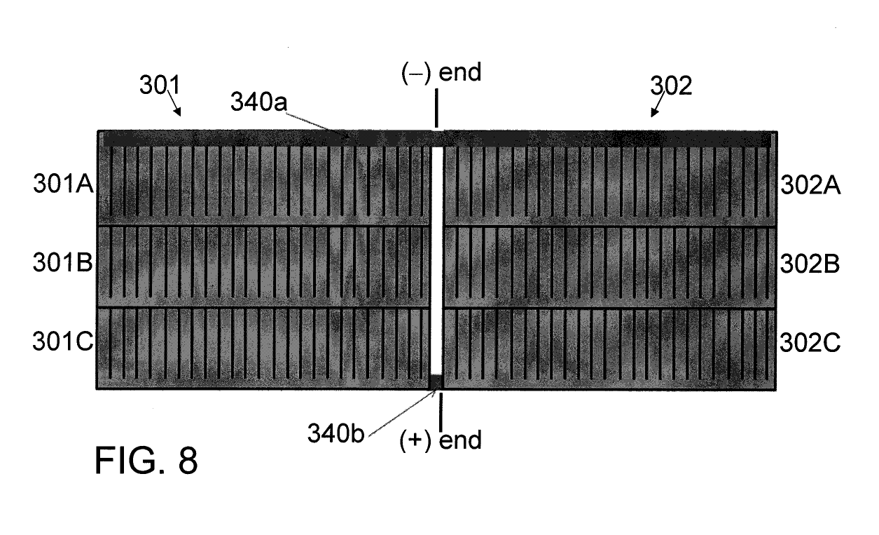

As further shown in FIG. 8, a first bus ribbon 340a may extend across a first, front surface of the first cell group 301 and a first, front surface of the second cell group 302, for example, across the front surfaces of solar cells 301A and 302A. A second bus ribbon 340b may extend across a second, back surface of the first cell group 301 and a second, back surface of the second cell group 302, for example, across back surfaces of solar cells 301C and 302C. Thus, a parallel connection between the positive terminal of the solar cell 301A may be established with the positive terminal of the solar cell 302A, and a parallel connection between the negative terminal of the solar cell 301C may be established with the negative terminal of the solar cell 302C. In particular, the second bus ribbon 340b allows for shorting of one of the first cell group 301 or the second cell group 302 that produces the higher voltage.

In conventional panels, interconnection members such as bus ribbons used for interconnecting cells are typically arranged around solar cells, which generally utilize space on a panel less efficiently, for example, as shown in FIG. 2A. However, in present embodiments as illustrated in FIG. 7, bus ribbons 340 disposed on the front and back surfaces of the cells in a PV module further maximize space on the panel. Thus, by minimizing areas on a panel for internal wiring and interconnection, embodiments make available more active surface area for the arrangement of cells on a panel, relative to conventional solar panels.

In particular, the smaller side of a panel may have a width that is about 250 mm or less. Thin film cells interconnected on a panel in a conventional arrangement, as shown in FIG. 2A, would have relatively small sizes and would accordingly generate small currents. Moreover, the conventional panel's limits in voltage would impose a limit to the number of cells that may be added to the available space on the conventional panel as shown in FIG. 2A. However, embodiments of the invention add flexibility to very narrow panels with current and voltage restrictions, by allowing for the current to double by connecting groups of cells in parallel, and improving control over voltage by the addition or removal of efficiently interconnected cells.

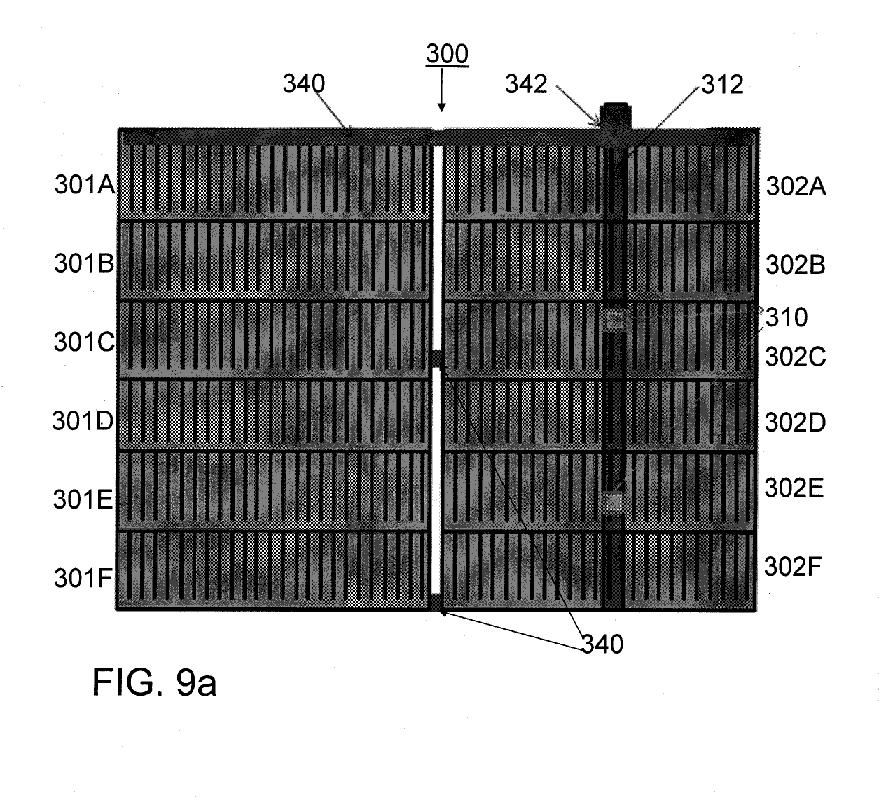

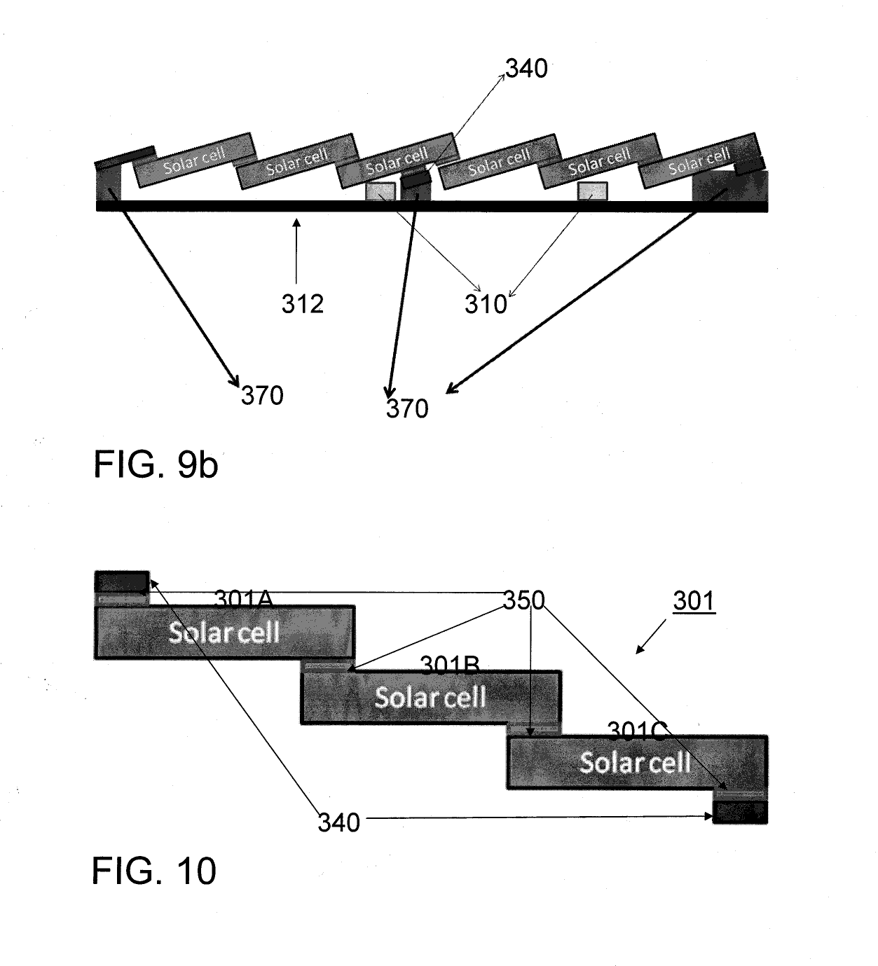

FIG. 9A shows a schematic top view of a PV module 300 connected to a bypass diode assembly 312, which includes a plurality of bypass diodes 310. In the illustrated embodiment, the bypass diode assembly 312 is provided at the back surface (shaded) of the PV module, for example, at the back surfaces of cells 302C and 302E. The diode assembly may be connected to the bus ribbon 340 at the front of the PV module, for example, at connection 342. Bus ribbon 340, disposed on the front surface at the front of the PV module, or disposed periodically on the back surfaces of the PV module, establishes a connection between the diode assembly and two groups of cells connected in parallel. FIG. 9B shows a schematic cross sectional view of the PV module 300 of FIG. 9A. As illustrated, each group of six shingled cells may be connected to a bypass diode 310 by connecting the bus ribbon 340 to the bypass diode assembly 312 at contact points 370. The contact points may be formed by solder, or a conductive adhesive.

In the illustrated embodiment, a bypass diode 310 is provided for every six shingled cells, in two groups of three cells connected in parallel. For example, a common bypass diode 310 is connected to the cell group consisting of 301A, 301B and 301C, connected in parallel with the cell group consisting of 302A, 302B and 302C. A common bypass diode 310 is also connected to the cell group consisting of 301D, 301E and 301F, connected in parallel with the cell group consisting of 302D, 302E and 302F. However, in other embodiments, a bypass diode may connect 8 or more cells, in groups connected in parallel, depending on the desired application.

FIG. 10 shows a schematic cross sectional view of a PV module, particularly of cell group 301. As illustrated, bus ribbons 340 are disposed over front and back surfaces of cell group 301, for example, over the front surface of solar cell 301A and over the back surface of solar cell 301C. The bus ribbon 340 may be adhered to a solar cell by a cured, insulating film 350. In the illustrated embodiment, the insulating film 350 connects solar cell 301A to solar cell 301B, and solar cell 301B to solar cell 301C. The insulating film 350 may have soldering or adhesive materials embedded within the film to establish an electrical connection between surfaces contacting each side of the insulating film 350, for example, between solar cells, or between a solar cell and an interconnecting surface such as bus ribbon 340. The insulating film can thus provide electrical contact between surfaces on each side of the insulating film, while at the same time preventing undesirable shunts along the shingled solar cells.

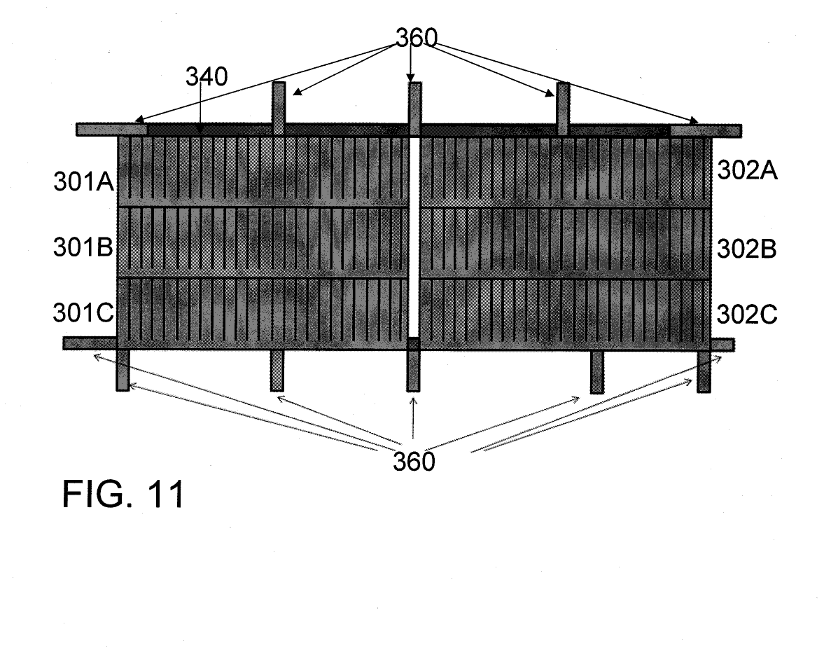

FIG. 11 shows an embodiment of a PV module with a plurality of possible lead extensions locations 360. The lead extensions provide for connection between the solar cells and an output terminal, such as a junction box, where the PV module's outlet wires are connected. These outlet wires are connected to a power circuitry to harvest the energy produced by the solar cells in the modules. The lead extensions may be provided in multiple locations of the PV module as illustrated, to increase the variety of positions at which the junction box may be placed on the panel that may in turn lead to ease of installation.

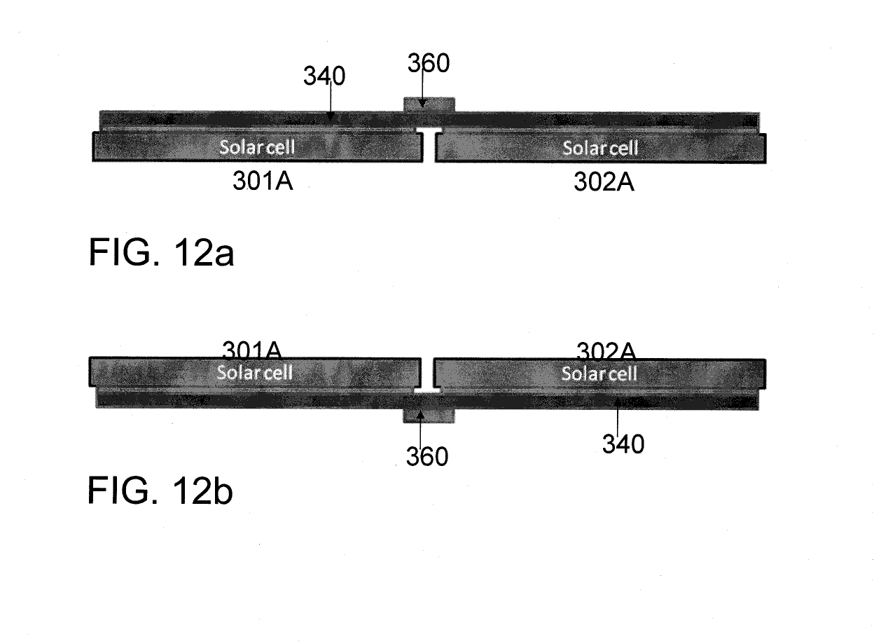

FIGS. 12A and 12B show cross sectional views of embodiment of a PV module with a plurality of lead extensions 360. FIG. 12A shows a schematic cross sectional view of a bus configuration on the front side of a PV module, and FIG. 12B shows a schematic cross sectional view of a bus configuration on the back side of a PV module. Lead extensions 360 may be placed anywhere along the bus ribbons 340.

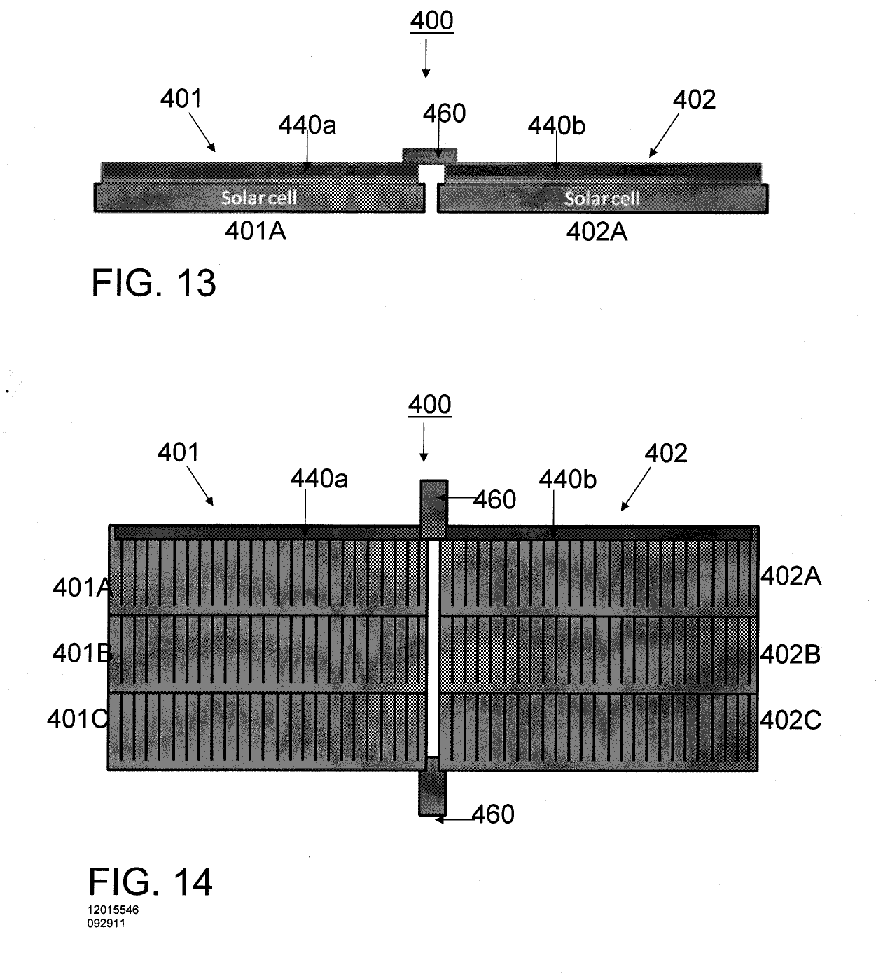

FIGS. 13 and 14 show a PV module 400 according to another embodiment. In the illustrated embodiment, the bus ribbon does not extend continuously across the surface of cell groups 401 and 402, as for the PV module shown in FIGS. 12A and 12B. Rather, in the illustrated embodiment, a first bus ribbon 440a extends across the front surface of solar cell 401A, and a second bus ribbon 440b extends across the front surface of solar cell 402A. The lead extension 460 may be slightly wider than for the PV module shown in FIGS. 12A and 12B, to secure a connection between bus ribbons 440a and 440b. Thus, the lead extension 460 in the present embodiment may function as both connecting parallel groups of cells, and connecting the cells to a junction box.

Although aspects and advantages of the present inventions are described herein with respect to certain preferred embodiments, modifications of the preferred embodiments will be apparent to those skilled in the art. Thus, the scope of the present invention should not be limited to the foregoing description, but should be defined by the appended claims.

What is claimed is:

1. A PV module, comprising:
a first group of solar cells;
a second group of solar cells;
a first interconnection member extending across a first surface of the first group of solar cells and across a first surface of the second group of solar cells to connect the first and second groups of solar cells in parallel; and
a second interconnection member extending across a second surface of the first group of solar cells and across a second surface of the second group of solar cells.

2. The PV module of claim 1, wherein the second group of solar cells is connected to a first bypass diode, and wherein the second interconnection member connects the first group of solar cells to the first bypass diode.

3. The PV module of claim 1, wherein the first group of solar cells comprises a first solar cell connected in series to a second solar cell, and wherein the second group of solar cells comprises a first solar cell connected in series to a second solar cell.

4. The PV module of claim 2, wherein the bypass diode is connected to the first and second groups of solar cells such that the bypass diode inhibits reverse bias of the first or second group of solar cells when one or more cells of the first or second groups of solar cells are reverse biased.

5. The PV module of claim 3, wherein the first group of solar cells is arranged in a shingled relationship such that a surface of the second solar cell comprising a terminal of a first polarity contacts a surface of the first solar cell comprising a terminal of a second polarity opposite the first polarity, and wherein the second group of solar cells is arranged in such a shingled relationship.

6. The PV module of claim 1, wherein the second interconnection member is configured to direct current through the first or second group of solar cells.

7. The PV module of claim 3, wherein the first group of solar cells comprises a third solar cell connected in series to the second solar cell, and wherein the second group of solar cells comprises a third solar cell connected in series to the second solar cell.

8. The PV module of claim 2, further comprising:
a third group of solar cells;
a fourth group of solar cells connected to a second bypass diode; and
a third interconnection member extending across a first surface of the third group of solar cells and across a first surface of the fourth group of solar cells to connect the third group of solar cells to the second bypass diode,
wherein the third group of solar cells is connected in series to the first group of solar cells, and wherein the fourth group of solar cells is connected in series to the second group of solar cells.

9. The PV module of claim 8, wherein the third group of solar cells comprises a first solar cell connected in series to a second solar cell, and wherein the fourth group of solar cells comprises a first solar cell connected in series to a second solar cell.

10. The PV module of claim 1, wherein a surface of the interconnection member is adhered to a surface of the first solar cell of the first group of solar cells and to a surface of the first solar cell of the second group of solar cells, by an insulating film cured therebetween, wherein the insulating film comprises a conductive element embedded in the insulating film.

11. The PV module of claim 1, further comprising a plurality of lead extensions connected to the first or the second interconnection member, wherein the lead extensions are configured to connect to a junction box that connects the PV module to a power circuitry.

12. The PV module of claim 1, wherein at least one of the first or second interconnection members extends continuously from the first group of solar cells to the second group of solar cells.

13. The PV module of claim 1, wherein at least one of the first or second interconnection members comprises a first interconnection portion connected to the first group of solar cells and a second separate interconnection portion connected to the second group of solar cells.

14. The PV module of claim 13, further comprising a lead extension connecting the first interconnection portion to the second interconnection portion, wherein the lead extension is configured to connect to a junction box that connects the PV module to a power circuitry.

15. A method of interconnecting a PV module, comprising:
connecting a plurality of solar cells in a first group of solar cells;
connecting a plurality of solar cells in a second group of solar cells;
connecting the first group of solar cells and the second group of solar cells in parallel by a first interconnection member extending across a first surface of the first group of solar cells and across a first surface of the second group of solar cells; and
connecting the first group of solar cells and the second group of solar cells by a second interconnection member extending across a second surface of the first group of solar cells and across a second surface of the second group of solar cells.

16. The method of claim 15, further comprising connecting the second group of solar cells to a first bypass diode, and connecting the first group of solar cells to the first bypass diode by the second interconnection member.

17. The method of claim 15, wherein connecting the plurality of solar cells in the first group comprises connecting a first solar cell in series to a second solar cell, and wherein connecting the plurality of solar cells in the second group comprises connecting a first solar cell in series to a second solar cell.

18. The method of claim 16, further comprising:
connecting a plurality of solar cells in a third group of solar cells;
connecting the third group of solar cells in series to the first group of solar cells;
connecting a plurality of solar cells in a fourth group of solar cells;
connecting the fourth group of solar cells to a second bypass diode;
connecting the fourth group of solar cells in series to the second group of solar cells; and
connecting the third group of solar cells to the second bypass diode by a third interconnection member.

19. The method of claim 18, wherein connecting the plurality of solar cells in the third group comprises connecting a first solar cell in series to a second solar cell, and wherein connecting the plurality of solar cells in the fourth group comprises connecting a first solar cell in series to a second solar cell.

20. The method of claim 15 further comprising connecting a plurality of lead extensions to the first or the second interconnection member, wherein the lead extensions are configured to connect to a junction box that connects the PV module to a power circuitry.
